(19) United States
(12) Patent Application Publication
(10) Pub. No.: US 2026/0074707 A1
(43) Pub. Date: Mar. 12, 2026

(54) RECEIVER CIRCUIT OF INTERFACE CIRCUIT AND OPERATING METHOD THEREOF

(71) Applicant: SAMSUNG ELECTRONICS CO., LTD., Suwon-si (KR)

(72) Inventors: Junyoung MAENG, Suwon-si (KR); Jaewoo Park, Suwon-si (KR); Seungyeob Baek, Suwon-si (KR); Myoungbo Kwak, Suwon-si (KR)

(73) Assignee: SAMSUNG ELECTRONICS CO., LTD., Suwon-si (KR)

(21) Appl. No.: 19/307,816

(22) Filed: Aug. 22, 2025

(30) Foreign Application Priority Data
Sep. 10, 2024 (KR) 10-2024-0123374

(51) Int. Cl. H03M 1/06; H03F 3/45; H03M 1/12

(52) U.S. Cl. CPC H03M 1/0678; H03F 3/45183; H03M 1/0607; H03M 1/1255; H03F 2200/151; H03F 2200/453

(57) ABSTRACT

A receiver circuit includes: a first sampling circuit that includes a first capacitor connected to a first node, and is configured to receive a first input voltage, and store a charge corresponding to the first input voltage in the first capacitor during a first period; and a buffer circuit includes a first transistor including a gate terminal connected to the first node, a source terminal connected to a first output node which is configured to output a first output voltage corresponding to the first input voltage, and a drain terminal connected to a second node that is AC grounded during the first period.

### CROSS-REFERENCE TO RELATED APPLICATION

This application claims priority to Korean Patent Application No. 10-2024-0123374, filed on Sep. 10, 2024 in the Korean Intellectual Property Office, the disclosure of which is incorporated by reference herein its entirety.

### BACKGROUND

### 1. Field

The present disclosure relates to a receiver circuit of an interface circuit, and an operating method of the receiver circuit.

### 2. Description of Related Art

In order to sample and process an input signal without distortion, a sample and hold circuit (S/H circuit) is used at an input terminal of an analog-digital converter. The S/H circuit samples the input analog voltage, holds a sampled value for a certain period of time, and transmits it to an analog-to-digital converter.

The S/H circuit may include a buffer circuit to drive the input capacity of the analog-to-digital converter. As data processing speed increases, a sampled value may be distorted by a parasitic capacitor in the buffer circuit.

### SUMMARY

Some embodiments may provide a receiver circuit for sampling an input voltage without distortion, and an operating method thereof.

According to an aspect of an embodiment, a receiver circuit includes: a first sampling circuit comprising a first capacitor connected to a first node, the receiver circuit being configured to receive a first input voltage, and store a first charge corresponding to the first input voltage in the first capacitor during a first period; and a buffer circuit comprising a first transistor including a gate terminal connected to the first node, a source terminal connected to a first output node which is configured to output a first output voltage corresponding to the first input voltage, and a drain terminal connected to a second node that is AC grounded during the first period.

According to an aspect of an embodiment, a receiver circuit includes: a first capacitor that is connected to a first node and configured to store a first charge corresponding to a first input voltage during a first period; a first transistor including a first gate terminal connected to the first node, a drain terminal connected to a second node, and a source terminal connected to a first output node configured to output a first output voltage corresponding to the first input voltage; and a first reset switch including a first end connected to the second node and a second end that is AC grounded, the first reset switch being turned on during the first period.

According to an aspect of an embodiment, an operating method of a receiver circuit, includes: receiving a first input voltage and performing a sampling operation for sampling a first charge corresponding to the first input voltage to a first capacitor connected to a first node; and performing a holding operation for generating a first output voltage corresponding to the first input voltage through a first output node by a first transistor including a gate terminal connected to the first node, a drain terminal connected to a second node, and a source terminal connected to the first output node, wherein the performing the sampling operation includes turning on of a first reset switch including a first end connected to the second node and a second end that is AC grounded.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 shows an interface circuit according to one or more embodiments;

FIG. 2 and FIG. 3 are circuit diagrams of a sample and hole (S/H) circuit according to one or more embodiments;

FIG. 4 are circuit diagrams of the S/H circuit according to one or more embodiments;

FIG. 5 is a circuit diagram of the S/H circuit according to one or more embodiments;

FIG. 6 and FIG. 7 are circuit diagrams of an S/H circuit according to one or more embodiments;

FIG. 8 is a timing diagram of the operation of the S/H circuit of FIG. 6 and FIG. 7;

FIG. 9 and FIG. 10 are circuit diagrams of an S/H circuit according to one or more embodiments;

FIG. 11 is a timing diagram of the operation of the S/H circuit of FIG. 9 and FIG. 10 according to one or more embodiments;

FIG. 12 and FIG. 13 are circuit diagrams of an S/H circuit according to one or more embodiments;

FIG. 14 is a timing diagram of the operation of the S/H circuit of FIG. 12 and FIG. 13 according to one or more embodiments; and

FIG. 15 is a block diagram of a communication apparatus according to one or more embodiments.

### DETAILED DESCRIPTION

In the following detailed description, certain example embodiments are shown and described, simply by way of illustration. As those skilled in the art would realize, the described embodiments may be modified in various different ways, without departing from the spirit or scope of the present disclosure.

Accordingly, the drawings and description are to be regarded as illustrative in nature and not restrictive. Like reference numerals designate like elements throughout the specification. In the flowchart described with reference to the drawing, the order of operations may be changed, several operations may be merged, some operations may be split, and certain operations may not be performed.

In the present specification, expressions described in the singular may be construed in the singular or plural unless an explicit expression such as “one” or “single” is used. In the present specification, the terms including ordinal numbers such as first, second, etc. may be used to describe various elements, but the elements are not limited by the terms. The terms are used only for the purpose of distinguishing one element from another element.

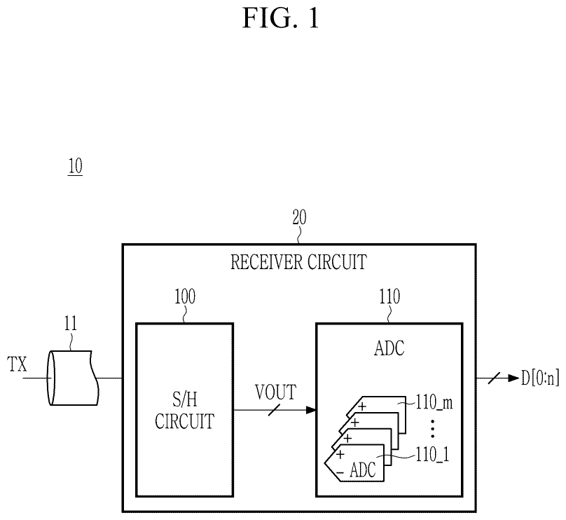

FIG. 1 shows an interface circuit according to one or more embodiments.

Referring to FIG. 1, an interface circuit 10 may include a channel 11 and a receiver circuit 20. In some embodiments, the interface circuit 10 may be an interface used for input/output of a memory device. The receiver circuit 20 may be connected with a transmitter circuit through the channel 11. In some embodiments, the channel 11 may be a through-silicon via (TSV).

In some embodiments, the interface circuit 10 may be a circuit for transmitting data to a memory device, for example, a non-volatile memory device. For example, the interface circuit 10 may be a circuit for various interfaces such as a universal serial bus (USB), a multimedia card (MMC), a PCIExpress (PCI-E), AT attachment (ATA), a serial AT attachment (SATA), parallel AT attachment (PATA), a small computer system interface (SCSI), a serial attached SCSI (SAS), an enhanced small disk interface (ESDI), integrated drive electronics (IDE), non-volatile memory express (NVMe), and the like.

The receiver circuit 20 may receive a transmission signal TX via the channel 11, sequentially determine a bit value of the transmission signal TX, and output a bit value D[0: n] of an input signal. The transmission signal TX may be an analog voltage signal. In some embodiments, the receiver circuit 20 may include a sample and hold (S/H) circuit 100 and an analog digital converter 110.

The S/H circuit 100 may generate a plurality of output voltages Vout based on the transmission signal TX. The S/H circuit 100 may alternately perform a sampling operation and a holding operation on the transmission signal TX (i.e., input voltage). The sampling operation may be an operation that samples the input voltage. The holding operation may be an operation of holding a sampled input voltage, generating an output voltage corresponding to the input voltage, and transmitting the output voltage to an analog-to-digital converter 110 in synchronization with a clock signal. In some embodiments, the S/H circuit 100 may include a sampling circuit and a flipped voltage follower (FVF) buffer. For example, the FVF buffer may include a feedback loop that includes a feedback capacitor and may have low output impedance. In addition, the FVF buffer may operate with increased bandwidth compared to a source follower.

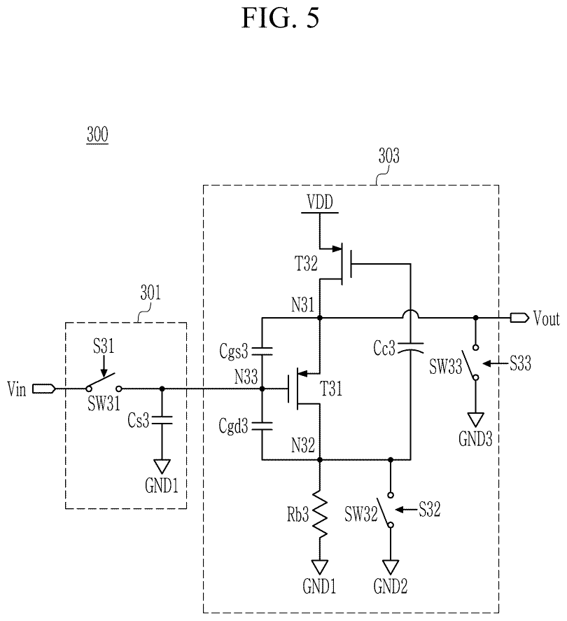

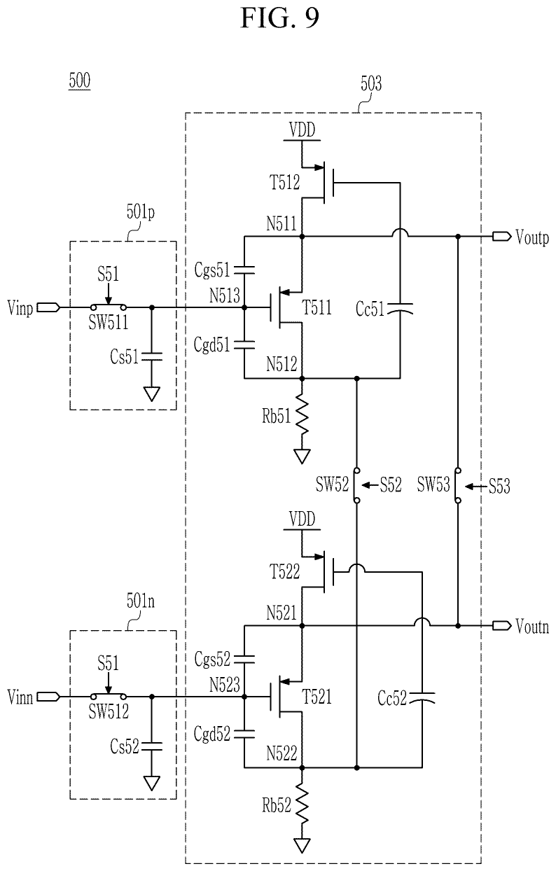

In some embodiments, the S/H circuit 100 may operate as a single input buffer or a differential input buffer. For example, when the S/H circuit 100 is a differential input buffer, the S/H circuit 100 may include a first sampling circuit that receives a non-inverted input signal corresponding to the transmission signal TX and a second sampling circuit that receives an inverted input signal. Hereinafter, the sample hold buffer 100 operating as a single input buffer will be described with reference to FIG. 5 to FIG. 8 and FIG. 12 to FIG. 14, and the S/H circuit 100 operating as a differential input buffer will be described with reference to FIG. 9 to FIG. 11.

The sampling circuit may include at least one sample switch. The sampling circuit may perform a sampling operation based on a sample switch control signal for controlling at least one sample switch.

In some embodiments, the FVF buffer may include at least one reset switch. At least one reset switch may be a switch to remove distortion of sampling values caused by a parasitic capacitor during the sampling operation. For example, at least one reset switch may be connected to AC ground. In some embodiments, the FVF buffer may respond to a plurality of reset switch control signals during the sampling operation to control at least one reset switch such that each of the reset switches is connected to the AC ground. As used in the present specification, the term “AC ground” refers to a node voltage condition in which a DC component is allowed to pass, while an AC component is connected to ground and thereby removed. That is, in such a configuration, high-frequency components or varying AC signals at a given node in the circuit are filtered out, and only a stable DC voltage is maintained.

The analog digital converter 110 may generate the bit value D[0: n] of the input signal based on each of the plurality of output voltages Vout received from the S/H circuit 100. In some embodiments, the analog digital converter 110 may be a time-interleaved analog digital converter. The analog-digital converter 110 may include a plurality of analog-digital converters 110_1 to 110_m(where m is an integer greater than or equal to 2) that receive inputs in common (or time-divisionally). Each of the plurality of analog-digital converters 110_1 to 110_mmay sample the input at different points in time. The plurality of analog-digital converters 110_1 to 110_m each may output a digital signal corresponding to the magnitude of the output voltage VOUT. Each of the plurality of analog-digital converters 110_1 to 110_mmay be synchronized to a clock signal, and the plurality of clock signals supplied to the plurality of analog-digital converters 110_1 to 110_mmay have different phases.

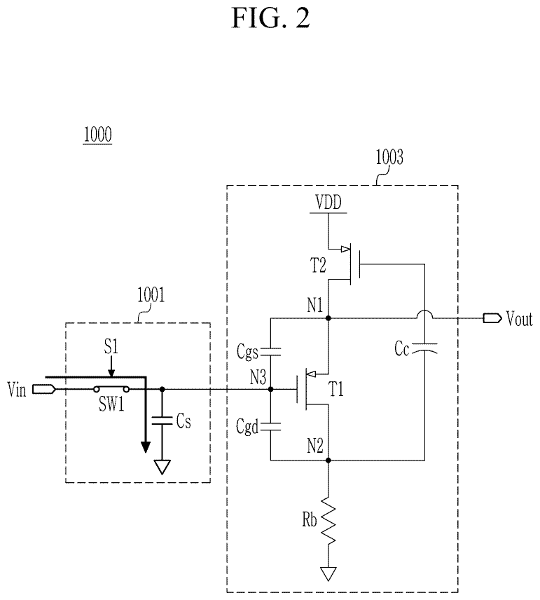

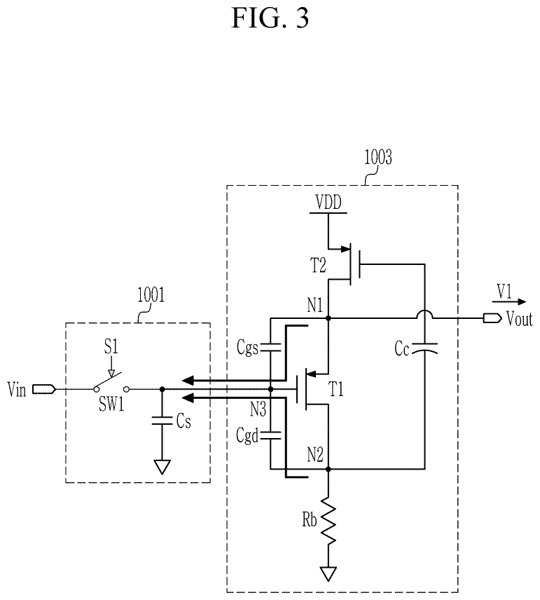

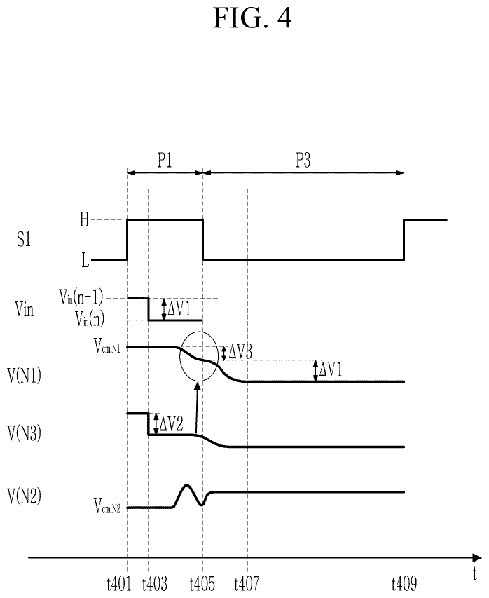

FIG. 2 and FIG. 3 are circuit diagrams of the S/H circuit according to one or more embodiments. FIG. 4 is a timing diagram of an operation of the S/H circuit of FIG. 3 according to one or more embodiments.

FIG. 2 is a circuit diagram of a case that the S/H circuit 1000 performs the sampling operation, and FIG. 3 is a circuit diagram of a case that the S/H circuit 1000 performing the holding operation.

As shown in FIG. 2 and FIG. 3, the S/H circuit 1000 may include a sampling circuit 1001 and a FVF buffer circuit 1003.

The sampling circuit 1001 may include a first switch SW1 and a sampling capacitor Cs.

The sampling circuit 1001 may receive an input voltage Vin through an input terminal. One end of the first switch SW1 may be connected to the input terminal and the other end may be connected to a third node N3. The first switch SW1 may be controlled by a first sample switch control signal S1. When the first switch SW1 is turned on, the input voltage Vin input through the input terminal may be transmitted to the third node N3.

The sampling capacitor Cs may be connected between the third node N3 and a ground voltage. The sampling capacitor Cs may store a charge based on a voltage of the third node N3. When the first switch SW1 is turned on, the charge stored in the sampling capacitor Cs may increase as the input voltage Vin is transmitted to the third node N3.

The FVF buffer circuit 1003 may include a plurality of transistors T1 and T2, a feedback capacitor Cc, and a resistor Rb.

A plurality of capacitors Cgs and Cgd may be parasitic capacitors between a gate terminal and a source terminal of the transistor T1 and between the gate terminal and a drain terminal of the transistor T1. Due to the parasitic capacitor, a voltage at the first node N1 and a voltage at the third node N3 may affect the charge stored in the sampling capacitor Cs. Accordingly, the FVF buffer circuit 1003 may output a voltage of a different magnitude than the input voltage.

The gate terminal of the first transistor T1 may be connected to the third node N3. The source terminal of the first transistor T1 may be connected to the first node N1. A drain terminal of the first transistor T1 may be connected to a second node N2. When the FVF buffer circuit 1003 operates at high frequency, a gate-source capacitor Cgs between the third node N3, which is the gate terminal of the first transistor T1, and the first node N1, and a gate-drain capacitor Cgd between the third node N3 and the second node N2 may affect the output voltage.

A gate terminal of the second transistor T2 may be connected to one end of the feedback capacitor Cc. A source terminal of the second transistor T2 may be connected to a power source voltage VDD. A drain terminal of the second transistor T2 may be connected to the first node N1. The second transistor T2 may perform a function that compensates for the operation of the first transistor T1.

In some embodiments, the first transistor T1 and the second transistor T2 may include P-type transistors. However, the present disclosure is not limited thereto, and the first transistor T1 and the second transistor T2 may be formed of N-type transistors.

The feedback capacitor Cc may be connected between the gate terminal of the second transistor T2 and the second node N2. In some embodiments, the feedback capacitor Cc may have a capacitance value that is larger than capacitance values of the parasitic capacitors Cgs and Cgd.

One end of the resistor Rb may be connected to the second node N2, and the other end may be connected to a ground power. The resistor Rb may control the intensity of the current flowing to the FVF buffer circuit 1003.

The FVF buffer circuit 1003 may output the output voltage Vout through an output terminal. The output terminal may be connected to the first node N1.

Referring to FIG. 4, the S/H circuit 1000 may perform the sampling operation and the holding operation alternately. The S/H circuit may perform the sampling operation during a first period P1 (t401 to t407) and the holding operation during a second period P3 (t407 to t409). The S/H circuit may perform the sampling operation during the first period P1 (t401 to t407) and the holding operation during the second period P3 (t407 to t409).

At t401, the first switch SW1 may be turned on by the first sample switch control signal S1 of high level H. During the first period P1, charges may be stored in the sampling capacitor Cs based on the input voltage Vin.

At t403, the input voltage Vin may transition from a first level (Vᵢₙ(n-1)) to a second level (Vᵢₙ(n)). Here, a difference between the first level (Vᵢₙ(n-1)) and the second level (Vᵢₙ(n)) may be ΔV1.

As the input voltage Vᵢₙ transitions from the first level (Vᵢₙ(n-1)) to the second level (Vᵢₙ(n)), a voltage at the third node N3 may be lowered by ΔV1.

While the S/H circuit 1000 operates at low frequency, the voltage of the first node N1, which is connected to the source terminal of the first transistor T1, and the second node N2, which is connected to the drain terminal of the first transistor T1, may be determined based on the input voltage Vᵢₙ transmitted to the third node N3. Accordingly, the output voltage Vout may be generated based on the input voltage Vᵢₙ.

However, when the S/H circuit 1000 operates at high frequency, a delay may occur until the voltages of the first node N1 and second node N2 change due to the voltage of the third node N3. Accordingly, the first node voltageV(N1) may transition at a later time than the time at which the voltage of the third node N3 transitions.

At t405 to t407, as the voltage of the third node N3 is applied to the gate terminal of the first transistor T1, the current flowing through the first transistor T1 may increase. The voltage of the second node N2 may increase due to the current flowing through the first transistor T1. A voltage applied to the gate terminal of the second transistor T2 may increase due to the increased voltage of the second node N2. Since the second transistor T2 is a P type transistor, the current flowing to the second transistor T2 may decrease as the voltage applied to the gate terminal increases. Accordingly, the voltages of the second node N2 and the first node N1 may decrease.

For example, the first node voltageV(N1) may be lowered by AV3. Changes in the first node voltageV(N1) may affect the third node voltageV(N3) through parasitic capacitors Cgs and Cgd. Specifically, to preserve the charge of the capacitor, a voltage difference between the two terminals of the gate-source capacitor Cgs and the gate-drain capacitor Cgd may need to be maintained. Accordingly, the third node voltageV(N3) may be affected by changes in the magnitude of the first node voltageV(N1), which is one end of the gate-source capacitor Cgs. Similarly, the third node voltageV(N3) may be affected by changes in the magnitude of the second node voltageV(N2), which is one end of the gate-drain capacitor Cgd.

That is, the third node voltageV(N3) may be affected by the first node voltageV(N1) and the second node voltageV(N2) through a gate-source capacitor Cgs and the gate-drain capacitor Cgd.

After t407, the first node voltageV(N61) may output a voltage, which is a value obtained by subtracting the sum of the change ΔV1 in the magnitude of the input voltage Vᵢₙ and AV3, as the output voltage Vout. In this case, the third node voltageV(N3) may have a voltage that changes to a different extent than the input voltage Vᵢₙ due to the influence of the change in the first node voltageV(N1). In addition, at t405 to t409, the second node voltageV(N2) may have a value smaller than a peak value of the second node voltageV(N2) at t403 to t405.

After the second section P3, the S/H circuit 1000 may transmit the output voltage Vout to an analog-to-digital converter (ADC) circuit. The ADC circuit may determine a bit value corresponding to the input voltage Vᵢₙ based on the output voltage Vout.

The first node voltageV(N1) may have a different voltage from the input voltage Vᵢₙ due to the influence of parasitic capacitors Cgs and Cgd. Accordingly, the ADC circuit connected to the rear end of the S/H circuit 1000 may determine a bit value corresponding to a voltage different from the input voltage as data.

FIG. 5 is a circuit diagram of the S/H circuit according to one or more embodiments.

As shown in FIG. 5, the S/H circuit 300 may include a sampling circuit 301 and an FVF buffer circuit 303.

The sampling circuit 301 may include a first switch SW31 and a sampling capacitor Cs3.

The sampling circuit 301 may receive the input voltage Vin through an input terminal. One end of the first switch SW31 may be connected to the input terminal and the other end may be connected to the third node N33. The first switch SW31 may be controlled by the first sample switch control signal S31. When the first switch SW31 is turned on, the input voltage Vin input through the input terminal may be transmitted to the third node N33.

The sampling capacitor Cs3 may be connected between the third node N33 and the ground voltage GND1. The first ground GND1 may be a ground power. The sampling capacitor Cs3 may store charges based on the voltage of the third node N33. When the first switch SW31 is turned on, the charge stored in the sampling capacitor Cs3 may increase as the input voltage Vin is transmitted to the third node N33.

The FVF buffer circuit 303 may include a plurality of transistors T31 and T32, a feedback capacitor Cc3, a resistor Rb3, a first reset switch SW32, and a second reset switch SW33.

A plurality of capacitors Cgs3 and Cgd3 may be parasitic capacitors between a gate terminal and a source terminal, and between the gate terminal and a drain terminal of a first transistor T31.

The gate terminal of the first transistor T31 may be connected to the third node N33. The source terminal of the first transistor T31 may be connected to the first node N31. The drain terminal of the first transistor T31 may be connected to the second node N32. When the FVF buffer circuit 303 operates at high frequency, a gate-source capacitor Cgs3 between the third node N33, which is the gate terminal of the first transistor T31, and the first node N31, and a gate-drain capacitor Cgd3 between the third node N33 and the second node N32 are shown in FIG. 5.

A gate terminal of a second transistor T32 may be connected to one end of the feedback capacitor Cc3. A source terminal of the second transistor T32 may be connected to the power source voltage VDD. A drain terminal of the second transistor T32 may be connected to the first node N31. The second transistor T32 may perform a function that compensates for the operation of the first transistor T31.

In some embodiments, the first transistor T31 and the second transistor T32 may include P-type transistors. However, the present disclosure is not limited to this, and the first transistor T31 and the second transistor T32 may be N-type transistors.

The feedback capacitor Cc3 may be connected between a gate terminal of the second transistor T32 and the second node N32.

One end of the resistor Rb may be connected to the second node N32 and the other end may be connected to the first ground GND1. The resistor Rb3 may control the intensity of the current flowing to the FVF buffer circuit 303.

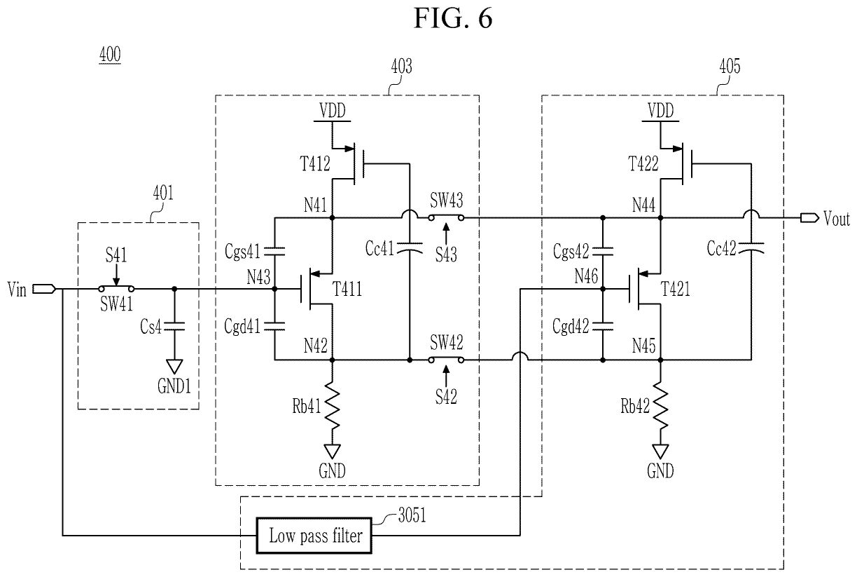

One end of the first reset switch SW32 may be connected to the second node N32, and the other end may be connected to the second ground GND2. The second ground GND2 may be an AC ground. The first reset switch SW32 may be controlled by the first reset switch control signal S32. When the first reset switch SW32 is turned on, the second node N32 may be AC biased through the second ground GND2. Accordingly, in the second node N32, an AC component is removed and only a DC component voltage may exist. For example, as will be described later, FIG. 6 illustrates an example of an AC ground implemented using a replica circuit 405. In FIG. 6, the replica circuit 405 is configured with the same FVF structure as the main buffer and includes a low-pass filter. Through this configuration, the first node N31 and the second node N32 can be maintained at a constant DC voltage. That is, the replica circuit 405 can replicate the operating environment of the FVF buffer 303 such that it is not affected by AC components.

One end of the second reset switch SW33 may be connected to the first node N31, and the other end may be connected to the third ground GND3. The third ground GND3 may be an AC ground. The second reset switch SW33 may be controlled by the second reset switch control signal S33. When the second reset switch SW33 is turned on, the first node N31 may be AC biased through the third ground GND3. Accordingly, at the first node N31, the AC component is removed and only the DC component voltage exist.

Specific examples of the AC grounds that can be connected to the first reset switch SW32 and the second reset switch SW33 will be described with reference to FIG. 6 to FIG. 8.

The FVF buffer circuit 303 may output the output voltage Vout through the output terminal. The output terminal may be connected to the first node N31.

The S/H circuit 300 performs the sampling operation and the holding operation alternately. The S/H circuit 300 may be connected to the AC ground GND2 and GND3 by turning on the first reset switch SW32 and the second reset switch SW33 while performing the sampling operation. The S/H circuit 300 may have no changes in the first node N31 and the second node N32 while performing the sampling operation. Accordingly, the third node N33 may not be affected by the changes in first node N31 and the second node N32. That is, the charge stored in the sampling capacitor Cs3 through the parasitic capacitor Cgs3 between the gate terminal and source terminal of the first transistor T31 and the parasitic capacitor Cgd3 between the gate terminal and drain terminal of the first transistor T31 may not be distorted.

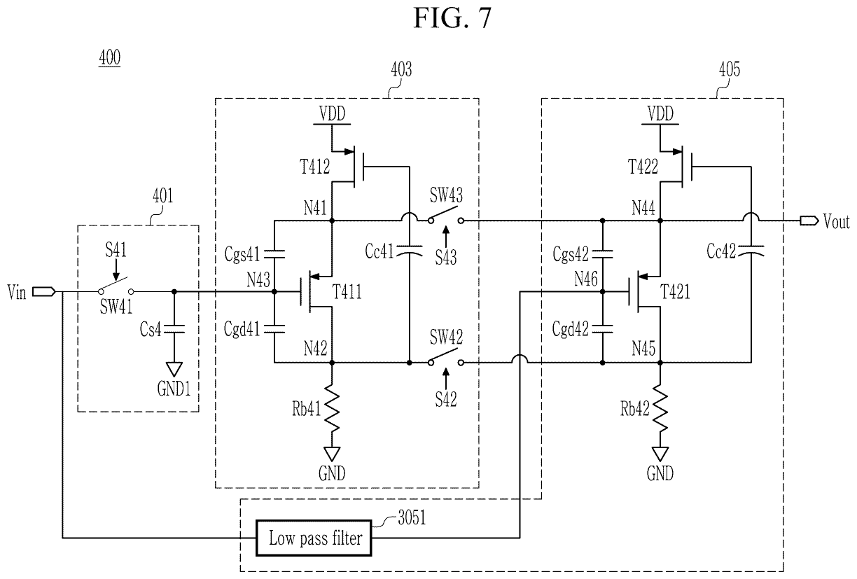

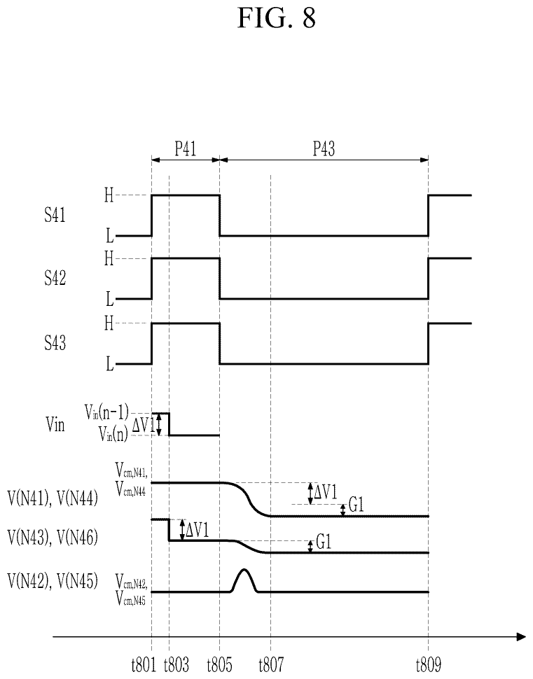

FIG. 6 and FIG. 7 are circuit diagrams of an S/H circuit according to one or more embodiments. FIG. 8 is a timing diagram of the operation of the S/H circuit of FIG. 6 and FIG. 7.

FIG. 6 is a circuit diagram of a case that an S/H circuit 400 performs the sampling operation, and FIG. 7 is a circuit diagram of a case that the S/H circuit 400 performs the holding operation.

In some embodiments, FIG. 6 and FIG. 7 are circuit diagrams of a case where a replica circuit is used as an example for implementing the AC ground in the S/H circuit 300 in FIG. 5.

As shown in FIG. 6 and FIG. 7, the S/H circuit 400 may include a sampling circuit 401, a FVF buffer circuit 403, and a replica circuit 405.

The sampling circuit 401 may include a first switch SW41 and a sampling capacitor Cs4.

The sampling circuit 401 may receive the input voltage Vin through an input terminal. One end of the first switch SW41 may be connected to an input terminal, and the other end may be connected to a third node N43. The first switch SW41 may be controlled by a first sample switch control signal S41. When the first switch SW41 is turned on, the input voltage Vin input through the input terminal may be transmitted to the third node N43.

The sampling capacitor Cs4 may be connected between the third node N43 and a ground voltage. The sampling capacitor Cs4 may store charge based on a voltage of the third node N43. When the first switch SW41 is turned on, the charge stored in the sampling capacitor Cs4 may increase as the input voltage Vin is transmitted to the third node N43.

The FVF buffer circuit 403 may include a plurality of transistors T411 and T412, a feedback capacitor Cc41, a resistor Rb41, a first reset switch SW42, and a second reset switch SW43.

A plurality of capacitors Cgs41 and Cgd41 may be parasitic capacitors between a gate terminal and a source terminal, and between the gate terminal and a drain terminal of a first transistor T411, respectively.

The gate terminal of the first transistor T411 may be connected to the third node N43. The source terminal of the first transistor T411 may be connected to a first node N41. A drain terminal of the first transistor T411 may be connected to a second node N42

A gate-source capacitor Cgs41 between the third node N43, which is the gate terminal of the first transistor T411, and the first node N41, and a gate-drain capacitor Cgd41 between the third node N43 and the second node N42 are shown in FIG. 6, these are important when the FVF buffer circuit 403 operates at high frequency.

A gate terminal of a second transistor T412 may be connected to one end of the feedback capacitor Cc41. A source terminal of the second transistor T412 may be connected to the power source voltage VDD. A drain terminal of the second transistor T412 may be connected to the first node N41. The second transistor T412 may perform a function that compensates for the operation of the first transistor T411.

In some embodiments, the first transistor T411 and the second transistor T412 may include P-type transistors. However, the present disclosure is not limited thereto, and the first transistor T411 and the second transistor T412 may include N-type transistors.

The feedback capacitor Cc41 may be connected between a gate terminal of the second transistor T412 and the second node N42.

One end of the resistor Rb41 may be connected to the second node N42, and the other end may be connected to the ground power. The resistor Rb41 may control the intensity of the current flowing to the FVF buffer circuit 403.

The FVF buffer circuit 403 may output the output voltage Vout through an output terminal. The output terminal may be connected to a fourth node N44, which is connected via the first node N41 and the second reset switch SW43.

One end of the first reset switch SW42 may be connected to the second node N42, and the other end may be connected to a fifth node N45 of the replica circuit 405. The first reset switch SW42 may be controlled by the first reset switch control signal S42. When the first reset switch SW42 is turned on, the second node N42 and the fifth node N45 may be connected.

One end of the second reset switch SW43 may be connected to the first node N41, and the other end may be connected to the fourth node N44. The second reset switch SW43 may be controlled by the second reset switch control signal S43. When the second reset switch SW43 is turned on, the first node N31 may be AC biased. Accordingly, at the first node N41, the AC component is removed and only the DC component voltage may exist.

The replica circuit 405 may be a circuit for providing the AC ground of the FVF buffer circuit 403. The replica circuit 405 may be implemented with components identical to at least some of the components of the FVF buffer circuit 403.

In some embodiments, the replica circuit 405 may include a low pass filter 3051, a plurality of transistors T421 and T422, a feedback capacitor Cc42, and a resistor Rb42.

The low pass filter 3051 may only pass a low frequency signal. That is, the low pass filter 3051 may filter out a high frequency component. For example, the low pass filter 3051 may block bands with frequencies greater than a predetermined cutoff frequency. Here, the cutoff frequency may be set based on the size of the resistor and the capacitance of the capacitor that make up the low pass filter 3051.

A plurality of capacitors Cgs41 and Cgd41 each may be a parasitic capacitor between a gate terminal and a source terminal, and between the gate terminal and a drain terminal of a third transistor T421, respectively.

The gate terminal of the third transistor T421 may be connected to a sixth node N46. The source terminal of the third transistor T421 may be connected to the fourth node N44. The drain terminal of the third transistor T421 may be connected to the fifth node N45.

A gate terminal of a fourth transistor T422 may be connected to one end of the feedback capacitor Cc42. A source terminal of the fourth transistor T422 may be connected to the power source voltage VDD. A drain terminal of fourth transistor T422 may be connected to the fourth node N44.

In some embodiments, the third transistor T421 and the fourth transistor T422 may include P-type transistors. However, the present disclosure is not limited to this, and the third transistor T421 and the fourth transistor T422 may be N-type transistors.

The feedback capacitor Cc42 may be connected between the gate terminal of the fourth transistor T422 and the fifth node N45.

One end of the resistor Rb42 may be connected to the fifth node N45, and the other end may be connected to the ground power. The resistor Rb42 may control the intensity of the current flowing to the replica circuit 405.

The plurality of transistors T421 and T422, the feedback capacitor Cc42, and the resistor Rb42 may each have the same characteristics as the plurality of transistors T411 and T412, the feedback capacitor Cc41, and the resistor Rb41, respectively. For example, a capacitance value of the feedback capacitor Cc42 may be the same as the capacitance value of the feedback capacitor Cc41, and a value of the resistor Rg42 may be the same as the value of the resistor Rb41.

In some embodiments, the replica circuit 405 may be placed in the same region as the buffer circuit 403. For example, an active region of the replica circuit 405 and an active region of the buffer circuit 403 may be identical.

Referring to FIG. 8, the S/H circuit 400 may alternately perform the sampling operation and the holding operation. The S/H circuit 400 may perform the sampling operation during a first period P41 (t801 to t805) and the holding operation during a second period P43 (t805 to t809).

Referring to FIG. 6 and FIG. 8 together, in the first period P41, the first switch SW41 may be turned on by the first sample switch control signal S41 of a high level H. The first reset switch SW42 may be turned on by the first reset switch control signal S42 of the high level H. The second reset switch SW43 may be turned on by the second reset switch control signal S43 of the high level H.

During the first period P41, charges may be stored in the sampling capacitor Cs4 based on the input voltage Vin.

At t803, the input voltage Vᵢₙ may transition from a first level (Vᵢₙ(n-1)) to a second level (Vᵢₙ(n)). Here, a difference between the first level (Vᵢₙ(n-1)) and the second level (Vᵢₙ(n)) may be ΔV1.

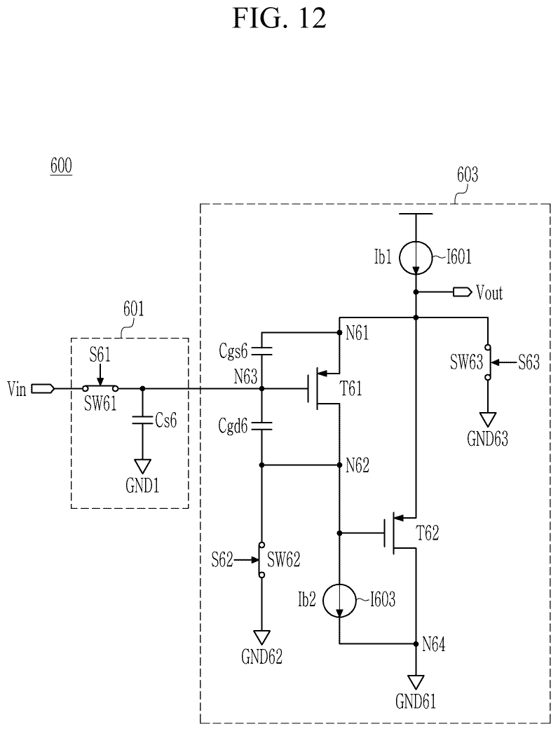

As the input voltage Vᵢₙ transitions from the first level (Vᵢₙ(n-1)) to the second level (Vᵢₙ(n)), the third node voltage V43 may be lowered by ΔV1. Since the first reset switch SW42 and the second reset switch SW43 are turned on, a voltage of the first node N41 and a voltage of the fourth node N44 may be the same, and a voltage of the second node N42 and a voltage of the fifth node N45 may be the same. That is, a common mode voltage (Vcm, N14) and a common mode voltage (Vcm, N44) are the same, and a common mode voltage (Vcm, N42) and a common mode voltage (Vcm, N45) may be the same. The common mode voltage Vom may be a reference potential of each node in a steady-state condition of a circuit employing a Flipped Voltage Follower (FVF) or Super Source Follower (SSF) structure, before an external input voltage is applied. For example, as described below, the common mode voltage Vcm may be set as an initial potential formed at output nodes and feedback nodes of an FVF buffer (e.g., 1003 in FIG. 2, 303 in FIG. 5, or 503 in FIG. 9), a replica circuit (405 in FIG. 6), or a buffer (603 in FIG. 12), prior to the initiation of a sampling operation. In the present specification, for example, the initial voltages of the output nodes N1, N31, N41, N44 and the feedback nodes N42, N45 are regarded as the common mode voltage Vcm, which may serve as a reference potential maintained while the circuit is in a pre-sampling state or during sampling when reset switches are turned on and the corresponding nodes are AC grounded.

Since the first reset switch SW42 and the second reset switch SW43 are turned on, there may be no voltage change in the first node N41, the second node N42, the fourth node N44, and the fifth node N45. Accordingly, the parasitic capacitors Cgs41 and Cgd41 may not affect the charge stored in the sampling capacitor Cs4.

Referring to FIG. 7 and FIG. 8 together, in the second period P43, the first switch SW41 may be turned off by the first sample switch control signal S41 of a low level L. The first reset switch SW42 may be turned off by the first reset switch control signal S42 of the low level L. The second reset switch SW43 may be turned off by the second reset switch control signal S43 of the low level L.

Since the first switch SW41 is turned off, the input voltage Vin may not be transmitted to the third node N43.

At t805 to t807, the current flowing through the first transistor T411 may increase as the voltage of the third node N43 is applied to the gate terminal of the first transistor T411. The voltage of the second node N42 may increase due to the current flowing through the first transistor T411. The voltage applied to the gate terminal of the second transistor T412 may increase due to the increased voltage of the second node N42. Since the second transistor T412 is a P type transistor, as the voltage applied to the gate terminal increases, the current flowing to the second transistor T412 may decrease. Accordingly, the voltage of the second node N42 and the first node N41 may decrease.

The voltage of the first node N41 may decrease by the amount of the sum of a change amount in the input voltage Vin and a voltage difference between the gate terminal and the source terminal of the first transistor T411. In FIG. 8, a voltage difference between the gate terminal and source terminal of the first transistor T411 is shown as a first offset G1. The first offset G1 may be based on a difference between an input voltage Vin and an output voltage Vout. In addition, the difference between the input voltage Vin and the output voltage Vout may be based on a gate-to-source voltage difference of a transistor T421. Information regarding the magnitude of the first offset G1 may be pre-stored, for example, in the form of a look-up table (LUT). The ADC circuit (110 of FIG. 1) may compensate for the first offset G1 by adding or subtracting a bit value corresponding to the first offset G1 to or from a bit value corresponding to the input voltage Vin, based on the pre-stored first offset G1.

After t807, a first node voltageV(N41) may be output a voltage obtained by subtracting the sum of the magnitude change in the input voltage Vin and the first offset G1 from the common voltage (Vcm, N41) as an output voltage Vout. Therefore, the output voltage Vout may be determined based on the charge stored in the sampling capacitor Cs by the input voltage Vin. Afterwards, it may be transmitted to the analog digital converter (110 of FIG. 1).

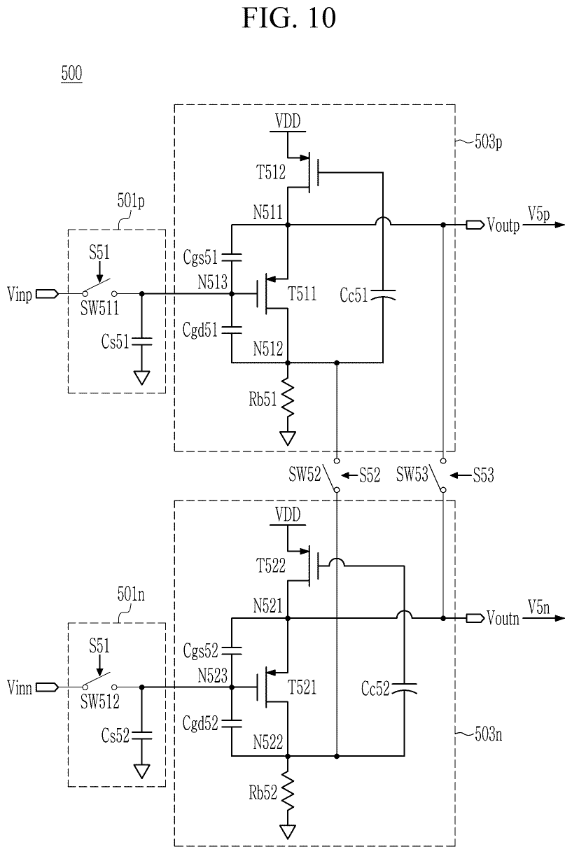

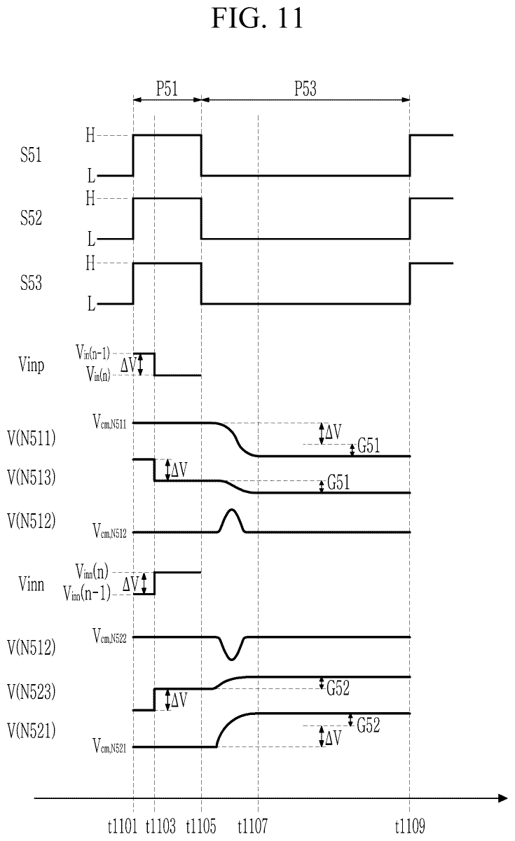

FIG. 9 and FIG. 10 are circuit diagrams of an S/H circuit according to one or more embodiments. FIG. 11 is a timing diagram of the operation of the S/H circuit of FIG. 9 and FIG. 10.

As shown in FIG. 9, an S/H circuit 500 may include a first S/H circuit 500p and a second S/H circuit 500n.

The first S/H circuit 500p may include a first sampling circuit 501p, a second sampling circuit 501n, and a FVF buffer circuit 503.

The first sampling circuit 501p may include a first switch SW511 and a first sampling capacitor Cs51.

The first sampling circuit 501p may receive a non-inverted input voltage Vinp through an input terminal. One end of the first switch SW511 may be connected to the input terminal, and the other end may be connected to a third node N513. The first switch SW511 may be controlled by a first sample switch control signal S51. When the first switch SW511 is turned on, the non-inverted input voltage Vinp input through the input terminal may be transmitted to the third node N513.

The sampling capacitor Cs51 may be connected between the third node N513 and the ground voltage. The sampling capacitor Cs51 may store charges based on a voltage of the third node N513. When the first switch SW511 is turned on, the charge stored in the sampling capacitor Cs51 may increase as the non-inverting input voltage Vinp is transmitted to the third node N513.

The second sampling circuit 501n may include a second switch SW512 and a sampling capacitor Cs52.

The second sampling circuit 501n may receive an inverted input voltage Vinn through an input terminal. One end of the second switch SW512 may be connected to the input terminal, and the other end may be connected to a third node N523. The second switch SW512 may be controlled by the first sample switch control signal S51. When the second switch SW512 is turned on, the inverted input voltage Vinn input through the input terminal may be transmitted to the third node N523.

The sampling capacitor Cs52 may be connected between the third node N523 and the ground voltage. The sampling capacitor Cs52 may store charges based on a voltage of the third node N523. When the second switch SW512 is turned on, the charge stored in the sampling capacitor Cs52 may increase as the inverted input voltage Vinn is transmitted to the third node N523.

The FVF buffer circuit 503 may include a plurality of transistors T511, T512, T521, and T522, feedback capacitors Cc51 and Cc52, resistors Rb51 and Rb52, a first reset switch SW52, and a second reset switch SW53.

In FIG. 9, a plurality of capacitors Cgs51 and Cgd51 may be parasitic capacitors between a gate terminal and a source terminal, and between the gate terminal and a drain terminal of a first transistor T511. In addition, a plurality of capacitors Cgs52 and Cgd52 may be parasitic capacitors between a gate terminal and a source terminal, and between the gate terminal and a drain terminal of a second transistor T521.

The gate terminal of the first transistor T511 may be connected to a thirteenth node N513. The source terminal of the first transistor T511 may be connected to an eleventh node N511. The drain terminal of the first transistor T511 may be connected to a twelfth node N512. A gate-source capacitor Cgs51 between the thirteenth node N513, which is the gate terminal of the first transistor T511, and the eleventh node N511, and a gate-drain capacitor Cgd51 between the thirteenth node N513 and the twelfth node N512 are shown in FIG. 9, these are important when the FVF buffer circuit 503 operates at high frequency.

The gate terminal of the second transistor T512 may be connected to one end of the feedback capacitor Cc51. The source terminal of the second transistor T512 may be connected to the power source voltage VDD. The drain terminal of the second transistor T512 may be connected to the eleventh node N511. The second transistor T512 may perform a function that compensates for the operation of the first transistor T511.

A gate terminal of a third transistor T521 may be connected to a twenty-third node N523. A source terminal of the third transistor T521 may be connected to a twenty-first node N521. A drain terminal of the third transistor T521 may be connected to a twenty-second node N522. A gate-source capacitor Cgs52 between the twenty-third node N523, which is a gate terminal of the third transistor T521, and the twenty-first node N521, and a gate-drain capacitor Cgd52 between the twenty-third node N523 and the twenty-second node N522 are shown in FIG. 10, these are important when the FVF buffer circuit 503 operates at high frequency.

A gate terminal of a fourth transistor T522 may be connected to one end of the feedback capacitor Cc52. A source terminal of the fourth transistor T522 may be connected to the power source voltage VDD. A drain terminal of the fourth transistor T522 may be connected to the twenty-first node N521. The fourth transistor T522 may perform a function that compensates for the operation of the third transistor T521.

In some embodiments, the first transistor T511, the second transistor T512, the third transistor T521, and the fourth transistor T522 may include P-type transistors. However, the present disclosure is not limited thereto, and the first transistor T511, the second transistor T512, the third transistor T521, and the fourth transistor T522 may be N-type transistors.

The feedback capacitor Cc51 may be connected between the gate terminal of the second transistor T512 and the twelfth node N512.

The feedback capacitor Cc52 may be connected between the gate terminal of the fourth transistor T522 and the twenty-second node N522.

One end of the resistor Rb51 may connected to the twelfth node N512, and the other end may be connected to the ground power.

One end of the resistor Rb52 may be connected to the twenty-second node N522, and the other end may be connected to the ground power. The resistors Rb51 and Rb52 may control the intensity of the current flowing to the FVF buffer circuit 503.

One end of the first reset switch SW52 may be connected to the twelfth node N512, and the other end may be connected to the twenty-second node N522. The first reset switch SW52 may be controlled by a first reset switch control signal S52. When the first reset switch SW52 is turned on, the twelfth node N512 and the twenty-second node N522 may be connected.

One end of the second reset switch SW53 may be connected to the eleventh node N511, and the other end may be connected to the twenty-first node N521. The second reset switch SW53 may be controlled by a second reset switch control signal S53. When the second reset switch SW53 is turned on, the eleventh node N511 and the twenty-first node N521 may be connected.

The FVF buffer circuit 503 may output an output voltage through a plurality of output terminals. The first output terminal may be connected to the eleventh node N511. The FVF buffer circuit 503 may output a non-inverted output voltage Voutp through a first output terminal. The FVF buffer circuit 503 may output an inverted output voltage Voutn through a second output terminal.

Referring to FIG. 11, the S/H circuit 500 may alternately perform the sampling operation and the holding operation. The S/H circuit 500 may perform the sampling operation for a first period P51 (t1101 to t1105) and may perform the holding operation for a second period P53 (t1105 to t1109).

Referring to FIG. 9 and FIG. 11 together, in the first period P51, the first switch SW511 and the second switch SW512 may be turned on by the first sample switch control signal S51 of a high level H. The first reset switch SW52 may be turned on by the first reset switch control signal S52 of the high level H. The second reset switch SW53 may be turned on by the second reset switch control signal S53 of the high level H.

During the first period P51, charges may be stored in the sampling capacitors Cs51 and Cs52 based on the corresponding input voltages Vinp and Vinn.

At t1103, the non-inverting input voltage Vinp may transition from a first level (Vᵢₙₚ(n-1)) to a second level (Vᵢₙₚ(n)). In addition, the inverted input voltage Vinn may transition from a third level (Vᵢₙₚ(n-1)) to a fourth level (Vᵢₙₙ(n)). Here, a difference between the first level (Vᵢₙₚ(n-1)) and the second level (Vᵢₙₚ(n)) and a difference between the third level (Vᵢₙₙ(n-1)) and the fourth level (Vᵢₙₙ(n)) may be V.

As the non-inverting input voltage Vᵢₙₚ transitions from the first level first level (Vᵢₙₚ(n-1)) to the second level (Vᵢₙₚ(n)), a voltage of the thirteenth node N513 may be lowered by V. As the inverted input voltage Vᵢₙₙ transitions from the third level (Vᵢₙₙ(n-1)) to the fourth level (Vᵢₙₙ(n)), a voltage of the twenty-third node N523 may increase by V.

Since the first reset switch SW52 is turned on, the voltage of the twelfth node N512 and the voltage of the twenty-second node N522 may be maintained the same. In addition, since the second reset switch SW53 is turned on, the voltage of the eleventh node N511 and the voltage of the twenty-first node N521 may be maintained the same. That is, a common mode voltage (Vcm, N511) and a common mode voltage (Vcm, N521) may be the same, and a common mode voltage (Vcm, N512) and a common mode voltage (Vcm, N522) may be the same.

Since the first reset switch SW52 and the second reset switch SW53 are turned on, the non-inverting input voltage Vinp and the inverting input voltage Vinn may not change due to changes in the eleventh node N511, the twelfth node N512, the twenty-first node N521, and the twenty-second node N522.

Referring to FIG. 10 and FIG. 11 together, in the second period P53, the first switch SW511 and the second switch SW512 may be turned off by the first sample switch control signal S51 of a low level L. The first reset switch SW52 may be turned off by the first reset switch control signal S52 of the low level L. The second reset switch SW53 may be turned off by the second reset switch control signal S53 of the low level L.

Since the first switch SW511 and the second switch SW512 are turned off, the non-inverting input voltage Vinp may not be transmitted to the thirteenth node N513, and the inverting input voltage Vinn may not be transmitted to the twenty-third node N523.

At t1105 to t1107, as the voltage of the thirteenth node N513 is applied to the gate terminal of the first transistor T511, the current flowing through the first transistor T511 may increase. The voltage of the twelfth node N512 may increase due to the current flowing through the first transistor T511. The voltage applied to the gate terminal of the second transistor T512 may increase due to the increased voltage of the twelfth node N512. Since the second transistor T512 is a P type transistor, as the voltage applied to the gate terminal increases, the current flowing to the second transistor T512 may decrease. Accordingly, the voltage of the twelfth node N512 and the eleventh node N511 may decrease.

The voltage of the eleventh node N511 may decrease by the sum of the amount of changed in the non-inverted input voltage Vinp and a voltage difference between the gate terminal and the source terminal of the first transistor T511. In FIG. 11, a voltage difference between the gate terminal and the source terminal of the first transistor T511 is shown as a first offset G51.

Similarly, as the voltage of the twenty-third node N523 is applied to the gate terminal of the third transistor T521, the current flowing through the third transistor T521 may decrease. The voltage of the twenty-second node N522 may be reduced by the current flowing through the third transistor T521. The voltage applied to the gate terminal of the fourth transistor T522 may decrease by the reduced voltage of the twenty-second node N522. Since the fourth transistor T522 is a P type transistor, the current flowing through the fourth transistor T522 may increase as the voltage applied to the gate terminal decreases. Accordingly, the voltage of the twenty-second node N522 and the twenty-first node N521 may increase.

The voltage of the twenty-first node N521 may increase by the sum of the amount of change in the inverted input voltage Vinn and a voltage difference between the gate terminal and the source terminal of the third transistor T521. In FIG. 11, a voltage difference between the gate terminal and the source terminal of the third transistor T521 is shown as a second offset G52. Here, the first offset G51 and the second offset G52 may have the same value.

After t1107, an eleventh node voltageV(N511) may output a voltage, which is a voltage obtained by subtracting the sum of the change V in the magnitude of the non-inverting output voltage Vinp and the first offset G51 from the common voltage (Vcm, N511) as the non-inverted output voltage Voutp. The twenty-first node voltageV(N521) may output a voltage obtained by adding the sum of the change V in the magnitude of the inverted input voltage Vinn and the second offset G52 to the common voltage (Vcm, N521) as the inverted output voltage Voutn.

After the second period P53, the S/H circuit 500 may transmit the non-inverted output voltage Voutp and the inverted output voltage Voutn to the ADC circuit (110 in FIG. 1). The ADC circuit (110 in FIG. 1) may determine a bit value corresponding to the input voltages Vinp and Vinn based on the non-inverted output voltage Voutp and the inverted output voltage Voutn.

The S/H circuit 500 may perform the sampling operation by connecting the source terminal and the drain terminal of the first transistor T511, which receives the non-inverted input voltage Vinp in the first period P51, and the source terminal and the drain terminal of the third transistor T513, which receives the inverted input voltage Vinn. That is, the eleventh node N511 and the twenty-first node N521 may have common voltages (Vcm, N511 and Vcm, N521), and the twelfth node N512 and the twenty-second node N522 can have common voltages (Vcm, N512 and Vcm, N522). Accordingly, the voltage change occurring at the source terminal and the drain terminal of the first transistor T511 due to the non-inverting input voltage Vinp and the voltage change occurring at the source terminal and the drain terminal of the third transistor T521 due to the inverting input voltage Vinn may not occur. Therefore, there may be no distortion of the sampling capacitor Cs due to the parasitic capacitors Cgs51 and Cgd51 of the first transistor T511 and the parasitic capacitors Cgs52 and Cgd52 of the third transistor T521.

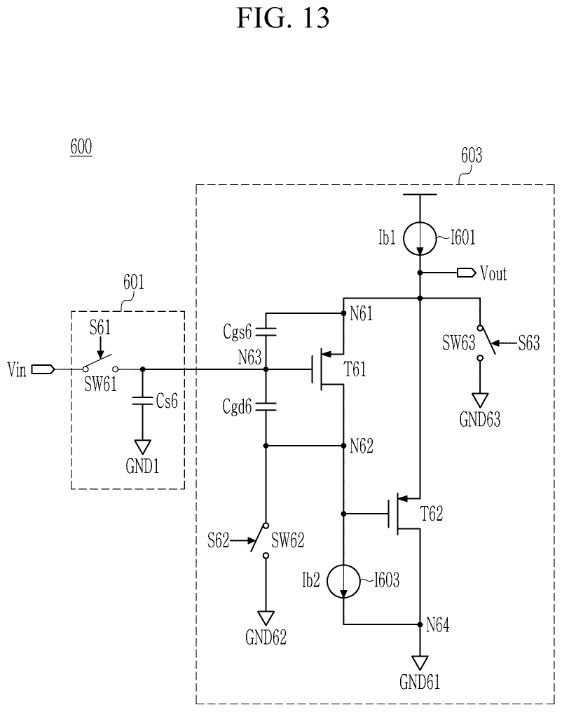

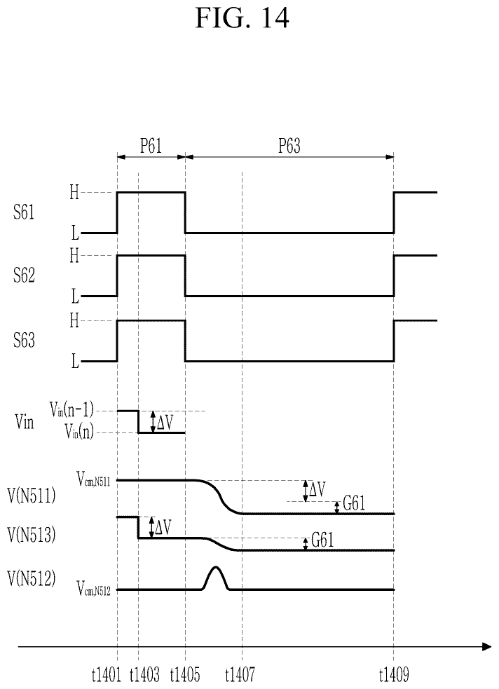

FIG. 12 and FIG. 13 are circuit diagrams of an S/H circuit according to one or more embodiments. FIG. 14 is a timing diagram of the operation of the S/H circuit of FIG. 12 and FIG. 13.

FIG. 12 is a circuit diagram of a case that an S/H circuit 600 performs the sampling operation, and FIG. 13 is a circuit diagram of a case that the S/H circuit 600 performs the holding operation.

As shown in FIG. 12 and FIG. 13, the S/H circuit 600 may include a sampling circuit 601 and a buffer circuit 603.

The sampling circuit 601 may include a first switch SW61 and a sampling capacitor Cs6.

The sampling circuit 601 may receive an input voltage Vin through an input terminal. One end of the first switch SW61 may be connected to the input terminal, and the other end may be connected to a third node N63. The first switch SW61 may be controlled by a first sample switch control signal S61. When the first switch SW61 is turned on, the input voltage Vin input through the input terminal may be transmitted to the third node N63.

The sampling capacitor Cs6 may be connected between the third node N63 and the ground voltage. The sampling capacitor Cs6 may store charges based on a voltage of the third node N63. When the first switch SW61 is turned on, the charge stored in the sampling capacitor Cs6 may increase as the input voltage Vin is transmitted to the third node N63.

The buffer circuit 603 may include a super source follower (SSF). The super source follower has a large input resistance and a low output resistance, and thus it may output the received input signal as an output signal with almost no loss.

The buffer circuit 603 may include a plurality of transistors T61 and T62, a first reset switch SW62, a second reset switch SW63, a first current source 1601, and a second current source 1603.

A plurality of capacitors Cgs6 and Cgd6 may be parasitic capacitors between a gate terminal and a source terminal, and between the gate terminal and a drain terminal of a first transistor T61.

The gate terminal of the first transistor T61 may be connected to the third node N3. The source terminal of the first transistor T61 may be connected to a first node N61. The drain terminal of the first transistor T61 may be connected to a second node N62. While the buffer circuit 603 operates at high frequency, a gate-source capacitor Cgs6 between the third node N63, which is the gate terminal of the first transistor T61, and the first node N61, and a gate-drain capacitor Cgd6 between the third node N63 and the second node N62 are shown in FIG. 12, these are important when the buffer circuit 603 operates at high frequency.

A gate terminal of the second transistor T62 may be connected to the second node N62. A source terminal of the second transistor T62 may be connected to a first ground GND61 (i.e., fourth node N64). A drain terminal of the second transistor T62 may be connected to the first node N61.

In some embodiments, the first transistor T61 may be a P-type transistor and the second transistor T62 may include an N-type transistor. However, the present disclosure is not limited thereto, and the first transistor T1 and the second transistor T2 may be N-type transistors or P-type transistors.

A first current source 1601 may control a current input to the first node N61. The first current 1601 may provide a first current lb1 to the first node N61.

A second current source 1603 may be connected between the second node N62 and the fourth node N64. The second current 1603 may provide a second current lb2 to the fourth node N64.

The source terminal of the first transistor T61 is driven by the first current source 1601, and the drain terminal of the first transistor T61 and the gate terminal of the second transistor T62 may be driven by the second current source 1603. The current flowing into the drain terminal of the second transistor T62 may be a value obtained by subtracting the second current lb2 from the first current lb1. The first current lb1 may be greater than the second current Ib2.

A drain voltage of the first transistor T601 may be set by a gate-source voltage of the second transistor T62.

One end of the first reset switch SW62 may be connected to the second node N62, and the other end may be connected to a second ground GND62. The second ground GND62 may be an AC ground. The first reset switch SW62 may be controlled by a first reset switch control signal S62. When the first reset switch SW62 is turned on, the second node N62 may be AC biased through the second ground GND62. Accordingly, in the second node N62, an AC component is removed and only a DC component voltage may exist.

One end of the second reset switch SW63 may be connected to the first node N61, and the other end may be connected to a third ground GND63. Third ground GND63 may be the AC ground. The second reset switch SW63 may be controlled by a second reset switch control signal S63. When the second reset switch SW63 is turned on, the first node N61 may be AC biased through the third ground GND3. Accordingly, at the first node N61, the AC component is removed and only the DC component voltage may exist.

The buffer circuit 603 may output an output voltage Vout through an output terminal. The output terminal may be connected to the first node N61.

Referring to FIG. 14, the S/H circuit 600 may alternately perform the sampling operation and the holding operation. The S/H circuit 600 may perform the sampling operation during a first period P61 (t1401 to t1405) and the holding operation during a second period P63 (t1405 to t1409).

At t1401, the first switch SW61 may be turned on by the first sample switch control signal S61 of a high level H. The first reset switch SW62 may be turned on by the first reset switch control signal S62 of the high level H. The second reset switch SW63 may be turned on by the second reset switch control signal S63 of the high level H.

Referring to FIG. 12, during the first period P61, charges may be stored in the sampling capacitor Cs6 based on the input voltage Vin.

At t1403, the input voltage Vin may transition from a first level (Vᵢₙ(n-1)) to a second level (Vᵢₙ(n)). Here, a difference between the first level (Vᵢₙ(n-1)) and the second level (Vᵢₙ(n)) may be V.

As the input voltage Vin transitions from the first level (Vᵢₙ(n-1)) to the second level (Vᵢₙ(n)), a voltage of the third node N63 may be lowered by ΔV.

Since the first reset switch SW62 is turned on, the third node N63 may be AC grounded. Accordingly, the voltage of the second node N62 may not be changed by the voltage of the third node N63.

In addition, since the second reset switch SW63 is turned on, the first node N61 may be AC grounded. Accordingly, the voltage of the first node N61 may not be changed by the voltage of the third node N63. That is, the first node N61 may be maintained at a common mode voltage (Vcm, N61), and the second node N62 may be maintained at a common mode voltage (Vcm, N62).

Referring to FIG. 13 and FIG. 14 together, in the second period P63, the first switch SW61 may be turned off by the first sample switch control signal S61 of the low level L. The first reset switch SW62 may be turned off by the first reset switch control signal S62 of the low level L. The second reset switch SW63 may be turned off by the second reset switch control signal S63 of the low level L.

Since the first switch SW61 is turned off, the input voltage Vin may not be transmitted to the third node N63.

At t1405 to t1407, the current flowing through the first transistor T61 may increase as the voltage of the third node N63 is applied to the gate terminal of the first transistor T61.

The current flowing through the second current source 1603 may be maintained constantly. The voltage of the first node N62 may decrease due to the current flowing through the first transistor T61. In addition, the voltage of the second node N62 may be increased.

However, the entire current flowing through the first current source 1601 may be the same. The voltage of the second node N62 may again be maintained at the common mode voltage (Vcm, N62).

The voltage of the first node N61 may decrease by a value obtained by adding the voltage difference between the gate terminal and the source terminal of the first transistor T61 to the amount of change in the input voltage Vin. In FIG. 14, the voltage difference between the gate terminal and the source terminal of the first transistor T61 is illustrated as a first offset G61.

After t1407, the first node voltageV(N61) may output a voltage obtained by subtracting the sum of the change V in the magnitude of the input voltage Vin and the first offset G61 from the common voltage (Vcm, N61), as the output voltage Vout.

After the second section P63, the S/H circuit 600 may transmit the output voltage Vout to the ADC circuit (110 in FIG. 1). The ADC circuit 110 may determine a bit value corresponding to the input voltage Vin based on the output voltage Vout.

The parasitic capacitors Cgs6 and Cgd6 may exist between the gate terminal and the source terminal, and between the gate terminal and the drain terminal of the first transistor T61. The S/H circuit 600 may connect the source terminal and the drain terminal of the first transistor T61, which receives the input voltage Vin in the first period P61, to the AC ground. Accordingly, the voltages of the first node N61 and the second node N62 may not change due to changes in the input voltage Vin through the parasitic capacitors Cgs6 and Cgd6. Therefore, the voltage of the first node N61 and the second node N62 may not have any influence on the sampling capacitor Cs6 by the parasitic capacitor Cgs6 and Cgd6 of the first transistor T61.

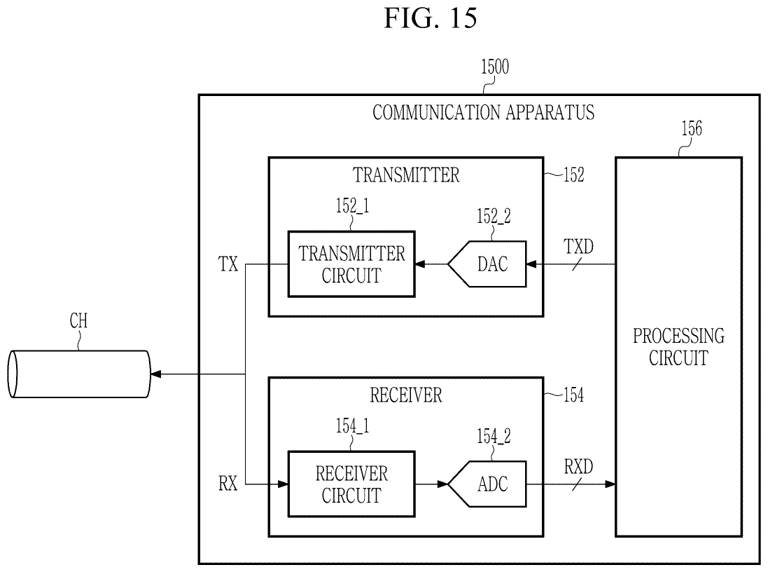

FIG. 15 is a block diagram of a communication apparatus according to one or more embodiments.

A communication apparatus 1500 may refer to any device that communicates with another communication apparatus through a communication channel CH. For example, the communication apparatus 1500 may be a portable device or a component included in a portable device, such as a laptop computer, a mobile phone, a wearable device, and the like. In addition, the communication apparatus 1500 may be a fixed device or a component included in a fixed device, such as a desktop computer, a server, a kiosk, and the like. In addition, the communication apparatus 1500 may also be used as a component of a means of transportation such as a vehicle or a ship. In some embodiments, the communication channel CH may include a wired channel, and the communication apparatus 1500 may perform communication based on any wired communication, for example, optical communication, Ethernet, peripheral component interconnect (PCI), PCI express (PCIe), universal serial bus (USB), serial ATA (SATA), and the like. In some embodiments, the communication channel CH may include a radio channel, and the communication apparatus 1500 may perform communication based on any wireless communication, a wireless local area network (WLAN), Bluetooth, long-term evolution (LTE), 5th generation (5G), and the like.

As shown in FIG. 15, the communication apparatus 1500 may include a transmitter 152, a receiver 154, and a processing circuit 156. When the communication channel CH includes a radio channel, the communication apparatus 1500 may further include at least one antenna connected to the transmitter 152 and the receiver 154. In some embodiments, the transmitter 152 and the receiver 154 may be implemented as a single component and collectively referred to as a transceiver.

The transmitter 152 may receive transmission data TXD from the processing circuit 156 and output a transmission signal TX to the communication channel CH based on the transmission data TXD. As shown in FIG. 15, the transmitter 152 may include a transmitter circuit 152_1 and a digital-to-analog converter (DAC) 152_2. The DAC 152_2 may convert the transmission data TXD received from the processing circuit 156 into an analog signal, and the transmitter circuit 152_1 may process the analog signal to generate a transmission signal TX. The transmitter circuit 152_1 may include circuits for processing analog signals, for example, an amplifier, a filter, or a mixer.

The receiver 154 may receive a received signal RX from the communication channel CH and provide received data RXD to the processing circuit 156 based on the received signal RX. As shown in FIG. 15, the receiver 154 may include a receiver circuit 154_1 and an analog-to-digital converter (ADC) 154_2. The receiver circuit 154_1 may process the received signal RX and may include circuits for processing the received signal RX, for example, an amplifier, a filter, or a mixer.

In some embodiments, the receiver circuit 154_1 may include the S/H circuit as described with reference to FIG. 2 to FIG. 14. In some embodiments, the S/H circuit may include a feedback loop to which a feedback capacitor is connected. The receiver circuit 154_1 may receive the received signal RX, and may AC ground an output node and the feedback loop connected to the ADC 154_2 while sampling the received signal RX. Since the output node and feedback loop are AC grounded, only DC components may exist in the output node and the feedback loop during sampling. Accordingly, a sampling value may not be changed by a parasitic capacitor between an input terminal (i.e., gate terminal) of the S/H circuit and the output node and between the input terminal and the feedback loop. That is, the receiver circuit 154_1 may control the S/H circuit such that the sampling value corresponding to the received signal RX is not distorted by a voltage change of the output node and the feedback loop.

The ADC 154_2 may generate received data RXD by converting the signal received from the receiver circuit 154_1. For high-speed communications, the ADC 154_2 may be a time-interleaved ADC including a plurality of sub analog-digital converters.

The processing circuit 156 may generate transmission data TXD based on information to be transmitted to another communication apparatus through the communication channel CH in a transmission mode, and provide the transmission data TXD to the transmitter 152. In addition, the processing circuit 156 may receive received data RXD from the transmitter 152 in a receiving mode, and may obtain information transmitted by another communication apparatus through the communication channel CH by processing the received data RXD.

The processing circuit 156 may include programmable components, components providing fixed functions, and/or reconfigurable components.

While certain example embodiments have been described, it is to be understood that embodiments of the present disclosure is not limited to the disclosed embodiments. On the contrary, it is intended to cover various modifications and equivalent arrangements included within the spirit and scope of the appended claims.

What is claimed is:

1. A receiver circuit comprising:
a first sampling circuit comprising a first capacitor connected to a first node, the first sampling circuit being configured to receive a first input voltage and store a first charge corresponding to the first input voltage in the first capacitor during a first period; and
a buffer circuit comprising a first transistor, wherein the first transistor comprises:
a gate terminal connected to the first node,
a source terminal connected to a first output node which is configured to output a first output voltage corresponding to the first input voltage, and
a drain terminal connected to a second node that is AC grounded during the first period.

2. The receiver circuit of claim 1, wherein the first output node is AC grounded during the first period.

3. The receiver circuit of claim 1, wherein the buffer circuit further comprises a first reset switch comprising a first end connected to the second node and a second end that is AC grounded, and
wherein the first reset switch is turned on during the first period.

4. The receiver circuit of claim 1, wherein the buffer circuit further comprises:
a second transistor comprising a drain terminal connected to the first output node, a gate terminal, and a source terminal connected to a power voltage; and
a second capacitor connected between the gate terminal of the second transistor and the second node.

5. The receiver circuit of claim 4, wherein the buffer circuit further comprises a second reset switch comprising a first end connected to the first output node and a second end that is AC grounded, and
wherein the second reset switch is turned on during the first period.

6. The receiver circuit of claim 1, wherein the receiver circuit further comprises a replica circuit comprising second components respectively corresponding to first components of the buffer circuit, and
wherein the buffer circuit and the replica circuit are connected during the first period and the buffer circuit and the replica circuit are disposed in the same first region.

7. The receiver circuit of claim 1, wherein the receiver circuit further comprises a second sampling circuit comprising a third capacitor connected to a third node, the receiver circuit being further configured to receive a second input voltage and store a second charge corresponding to the second input voltage in the third capacitor during the first period, and
wherein the buffer circuit further comprises a third transistor, and
wherein the third transistor comprises:
a gate terminal connected to the third node,
a source terminal connected to a second output node configured to output a second output voltage corresponding to the second input voltage, and
a drain terminal connected to a fourth node.

8. The receiver circuit of claim 7, wherein, during the first period, the first output node and the second output node are connected and the second node and the fourth node are connected.

9. The receiver circuit of claim 1, wherein the buffer circuit further comprises:
a second transistor comprising a gate terminal connected to the second node, a drain terminal connected to a ground, and a source terminal connected to the power voltage;
a first current source connected between the first output node and a power voltage;
a second current source connected between the second node and the ground;
a first reset switch comprising a first end connected to the second node and a second end that is AC grounded; and
a second reset switch comprising a first end connected to the first output node and a second end that is AC grounded, and
wherein the second reset switch is turned on during the first period.

10. The receiver circuit of claim 1, further comprising a time-interleaved analog-to-digital converter connected to the first output node and configured to generate a bit value corresponding to the first input voltage based on the first output voltage.

11. A receiver circuit comprising:
a first capacitor that is connected to a first node and configured to store a first charge corresponding to a first input voltage during a first period;
a first transistor comprising:
a gate terminal connected to the first node,
a drain terminal connected to a second node, and
a source terminal connected to a first output node configured to output a first output voltage corresponding to the first input voltage; and
a first reset switch comprising a first end is connected to the second node and a second end that is AC grounded, the first reset switch being turned on during the first period.

12. The receiver circuit of claim 11, further comprising:
a second transistor comprising a drain terminal connected to the first output node, a gate terminal, and a source terminal connected to a power voltage; and
a second capacitor connected between the gate terminal of the second transistor and the second node.

13. The receiver circuit of claim 12, further comprising a second reset switch comprising a first end is connected to the first output node and a second end is AC grounded,
wherein the second reset switch is turned on during the first period.

14. The receiver circuit of claim 11, further comprising:
a third capacitor that is connected to a third node and configured to store a second charge corresponding to a second input voltage during the first period; and
a third transistor comprising a gate terminal is connected to the third node, a drain terminal is connected to a fourth node, and a source terminal is connected to a second output node configured to output a second output voltage corresponding to the second input voltage,
wherein the first output node and the second output node are connected and the second node and the fourth node are connected during the first period.

15. The receiver circuit of claim 11, further comprising:
a second transistor comprising a gate terminal connected to the second node, a drain terminal connected to a ground power, and a source terminal connected to a power voltage;
a first current source connected between the first output node and the power voltage;
a second current source connected between the second node and the ground power;
a second reset switch comprising a first is connected to the first output node and a second end that is AC grounded,
wherein the second reset switch is turned on during the first period.

16. An operating method of a receiver circuit, the operating method comprising:
receiving a first input voltage and performing a sampling operation for sampling a first charge corresponding to the first input voltage to a first capacitor connected to a first node; and
performing a holding operation for generating a first output voltage corresponding to the first input voltage through a first output node by a first transistor comprising a gate terminal connected to the first node, a drain terminal connected to a second node, and a source terminal connected to the first output node,
wherein the performing the sampling operation comprises turning on of a first reset switch comprising a first end connected to the second node and a second end that is AC grounded.

17. The operating method of the receiver circuit of claim 16, wherein the performing the sampling operation comprises turning on of a second reset switch comprising a first end connected to the first output node and a second end that is AC grounded.

18. The operating method of the receiver circuit of claim 17, wherein the performing the holding operation comprises turning off of the first reset switch and the second reset switch.

19. The operating method of the receiver circuit of claim 17, wherein the performing the sampling operation comprises receiving a second input voltage and sampling a second charge corresponding to the second input voltage to a third capacitor connected to a third node,
wherein the performing the holding operation comprises generating a second output voltage corresponding to the second input voltage through the second output node by a third transistor comprising a gate terminal connected to the third node, a drain terminal connected to a fourth node, and a source terminal connected to the second output node, and
wherein the first reset switch is connected between the second node and the fourth node.

20. The operating method of the receiver circuit of claim 17, wherein the performing the holding operation comprises transmitting the first output voltage to a time-interleaved analog-to-digital converter connected to the first output node.
